(19) United States
(12) Patent Application Publication
(10) Pub. No.: US 2005/0282350 A1
(43) Pub. Date: Dec. 22, 2005

(54) Atomic layer deposition for filling a gap between devices

(76) Inventors: You-Hua Chou, Taipei (TW); Joung-Wei Liou, Jhudong Township (TW); Kuang-Yuan Hsu, Fongyuan City (TW); Chih-Lung Lin, Taipei (TW); Cheng-Yuan Tsai, Hsin-Chu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/873,505

(22) Filed: Jun. 22, 2004

(51) Int. Cl. H01L 21/76

(52) U.S. Cl. 438/424; 438/435; 438/786

(57) ABSTRACT

A method is provided for filling a trench or gap between a pair of semiconductor devices formed above a substrate. A liner is applied in a trench or gap between a pair of devices by atomic layer deposition to partially fill the trench or gap. The trench or gap is filled by a bulk fill process.

### FIELD OF THE INVENTION

The present invention relates to semiconductor fabrication generally, and more specifically to methods for filling gaps and trenches.

### BACKGROUND

It is known in the prior art to provide isolation walls between adjacent devices or device regions in integrated circuits, such as CMOS integrated circuits. For example, these isolation walls have been formed of a dielectric such as phosphor silicate glass (PSG), silicon oxy-nitride, silicon dioxide, or a combination of silicon dioxide and polycrystalline silicon.

FIG. 1 is a diagram of a pair of conventional devices 100, which may be thin film transistors, for example. Devices 100 may be any type of semiconductor device. In the example of FIG. 1, each device 100 has a polycrystalline silicon gate 110, gate dielectric 120 such as silicon nitride (SiN), and spacers 130, such as silicon oxy-nitride (SiOₓNₓ) or TEOS. In this example, the devices are separated by a gap X. For many types of devices, such as CMOS devices, it is also common for a trench beneath the gap between devices to extend downward into the substrate on which the devices are formed. As used herein, the term “gap” refers to the space between devices and above the top surface of the underlying substrate. The term “trench” refers to the space between devices and extending below the top surface of the underlying substrate.

Methods such as sub-atmospheric chemical vapor deposition (SA-CVD) and high density plasma chemical vapor deposition (HDP-CVD) have been used for filling the trench or gap between devices. As the material is deposited, growth progresses laterally as well as vertically making achievement of small lateral dimensions and precise dimensional control more difficult. Also, if the gap or trench has a high aspect ratio, it is common for material to be deposited on the side walls near the top at a greater rate than at the bottom, causing a bridge of material at the top of the gap or trench. Trapped voids are frequently formed, particularly in gaps and trenches whose depth is equal to or larger than their width.

FIG. 2 is a diagram of the devices 100 of FIG. 1, showing formation of the gap-filling layer 140 over the devices and in between them. Bridging has occurred, resulting in a void 150. Trapped voids are undesirable. For example, the void 150 does not have the desired isolation properties of the material 140 deposited in the gap or trench. The void 150 may result in contact leakage or a more serious short circuit. For example, poor gap fill on the interlayer dielectric leads to tungsten stringers, which can result in a contact short. Non-linear bias may also result.

The prior art deposition of PSG by HDP CVD has its limitations for gap fill between devices. Generally, this process cannot be used for filling gaps with a spacing X less than 350 angstroms, without the likelihood of void formation. Many current generation devices use a gap of less than 350 angstroms as a design rule for minimum distance. For example, the gap between pre-metal dielectric may be less than 180 angstroms.

In more advanced technologies with smaller geometries, even SA CVD may not be an adequate solution for filling the gap between devices. An alterative gap filling solution is desired.

### SUMMARY OF THE INVENTION

In some embodiments, a method for filling a trench or gap between a pair of semiconductor devices formed above a substrate comprises the steps of: applying a liner in a trench or gap between a pair of devices by atomic layer deposition to partially fill the trench or gap, and filling the trench or gap by a bulk fill process.

In some embodiments, a structure comprises: a pair of semiconductor devices formed above a substrate with a trench or gap therebetween, a liner formed in the trench or gap by atomic layer deposition to partially fill the trench or gap; and a layer of material filling the trench or gap.

In some embodiments, a method for applying an etch stop layer over a pair of semiconductor devices formed above a substrate comprises: applying a first etch stop layer by atomic layer deposition, the first etch stop layer comprising a first portion that is above each of the pair of devices and a second portion that is a liner in a gap between the pair of devices, wherein the gap has a dimension prior to the etch stop layer applying step of about an order of magnitude of an atomic group used to form the liner.

### BRIEF DESCRIPTION OF THE DRAWINGS

FIG. 1 is a cross sectional view of a pair of conventional devices.

FIG. 2 is a cross sectional view showing a void formed when the gap in FIG. 1 is filled using a conventional bulk fill process.

FIG. 3 is a cross sectional view showing a pair of devices for which the gap is filled using an exemplary method according to an embodiment of the invention.

FIG. 4 is a cross sectional view showing a pair of devices between which an etch stop layer is formed using an exemplary method according to another embodiment of the invention.

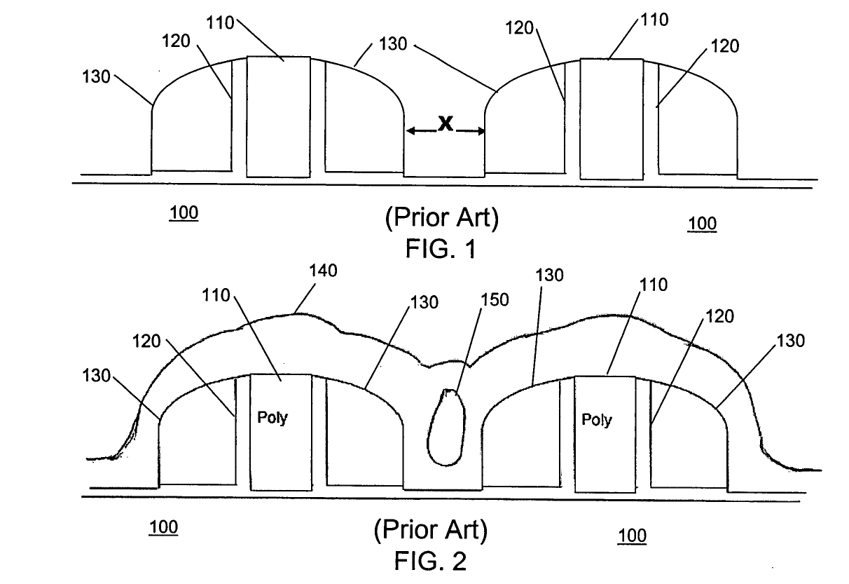

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

Methods and structures are described below, in which atomic layer deposition (ALD) is used to at least partially fill a gap or trench between devices. In some embodiments, ALD is used to form a liner for partially filling the gap or trench. In other embodiments, ALD is used to form an etch stop layer.

ALD uses sequential deposition of individual monolayers or fractions of a monolayer in a carefully controlled manner. In ALD, the surface on which material is to be deposited is alternately exposed to only one of two complementary chemical environments. Individual precursors are supplied to the apparatus one at a time. Between exposure steps, an inert gas purge or vacuum step is performed to remove any residual chemically active gas or by-products before introducing another precursor. These individual growth cycles are repeated. During each exposure step, precursor molecules react with the surface until all available surface sites are saturated. Precursor chemistries and process conditions are chosen such that no further reaction takes place once the surface is completely saturated. This makes ALD independent of variations in such process parameters as the amount of precursor supplied to the surface, precursor flow rate, partial pressure and the like. The thickness of the material deposited in each layer is a constant defined by the chemistry, and may be, for example between 0.1 and 1.0 angstroms. The film is grown layer-by-layer, and the total film thickness is determined by the number of cycles. ALD can achieve very high uniformity in the layer thickness across the entire surface on which material is deposited, including side walls and bottom walls of gaps and trenches, even those with high aspect ratios.

ALD has been used in other processes to provide good conformity and step coverage. For example, Gutsche et al., “Atomic Layer Deposition for Advanced DRAM Applications, http://www.fiiture-fab.com/documents.asp?grID=214&d ID=1900 visited Mar. 19, 2004 is incorporated by reference herein in its entirety. Gutsche et al. describe how ALD has been used for filling a trench between dynamic random access memory (DRAM) capacitors.

The gap filling problem presents different technical challenges than a trench between DRAMs. For example, the gap (spacing) on PMD (pre-metal dielectric) could be lower than 180 angstroms. When the spacing is lower than two to three hundred angstroms, the gap has the same order of magnitude as the size of an atomic group. Also, the PMD layer has a very critical thermal budget, especially for the deep-submicron technology. For example, heat treatment on NiSi is performed at temperatures lower than 450° C. Nevertheless, the inventor has determined that ALD is applicable to the gap-filling problem.

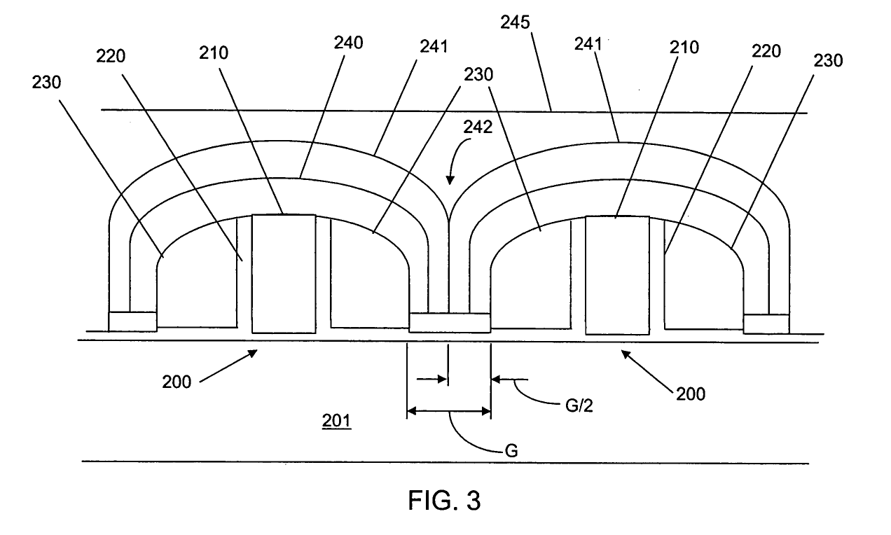

FIG. 3 is a cross sectional view of a pair of devices 200 between which is a gap that is filled using a first exemplary method. Devices 200 may be any type of semiconductor device. In the example of FIG. 3, each device 200 has a polycrystalline silicon gate 210, gate dielectric 220 such as silicon nitride (SiN), and spacers 230, such as silicon oxy-nitride (SiOₓNₓ) or TEOS.

An exemplary method is shown for filling a trench or gap between a pair of semiconductor devices 200 formed above a substrate 201 with phospho silicate glass. The substrate 201 may be a semiconductor wafer, or a layer of other dielectric material, such as glass, quartz and the like. The substrate may comprise a plurality of layers.

A liner 240, 241 is applied in the trench or gap between the pair of devices 200 by atomic layer deposition to partially fill the trench or gap, so that the trench or gap is reduced to a relatively shallow approximately V-shaped space 242. As noted above, ALD includes a plurality of cycles, in each of which a single layer of each precursor is applied, separated by an inert gas purge or vacuum. Thus a plurality of pairs of monolayers is deposited. In FIG. 3, only two of these layers 240, 241 are shown, but one or ordinary skill in the art will understand that the number of cycles (and precursor monolayer pairs deposited) can be any number necessary to deposit a desired thickness.

In the example, the gap between devices has an initial critical dimension G shown in FIG. 3. In a preferred embodiment, the number of ALD cycles is selected so that the thickness of the material deposited is at least one half the initial gap width G. Because ALD provides uniform coverage, the same layer thickness G/2 is deposited on both sides of the gap, so that the gap is substantially filled.

The remaining approximately V-shaped space 242 of the trench or gap has a low aspect ratio, and can subsequently be filled easily by a bulk fill process, such as chemical vapor deposition.

In some embodiments, the liner is formed of phospho silicate glass, and the liner is formed from precursors from the group consisting of TEOS, SiH₄, PH₃ and B₂H₆. For example, the liner applying step may include one or more cycles, wherein each cycle includes:
(a) depositing a monolayer of SiH₄, and
(b) depositing a monolayer of either PH₃ or B2H₆, and
(c) applying a low powered O₂/Ar plasma after the monolayer of either PH₃ or B₂H₆, which will not damage or sputter those monolayers. The O₂ plasma can provide both oxygen atoms and reaction power.

The cycle comprising steps (a), (b) and (c) is repeated a sufficient number of times to fill a critical dimension G of the trench or gap, except for the relatively shallow approximately V-shaped space 242. Then a bulk fill process such as PE-CVD or HDP-CVD may be used to fill the remaining V-shaped space 242 with a PSG film 245.

It is understood that ALD may be used to add additional material for PSG film 245 instead of the bulk fill process. However, a bulk fill process generally is faster than ALD.

FIG. 3 shows the product of the above described process. The structure comprises: a pair of semiconductor devices 200 formed above a substrate 201, with a trench or gap therebetween, a liner 240, 241 formed in the trench or gap by atomic layer deposition to partially fill the trench or gap, so that the trench or gap is reduced to a relatively shallow approximately V-shaped space 242, and a layer 245 of material filling the V-shaped space.

Since the ALD material components can be controlled by the gas ratio of PH₃ and SiH₄, even with the same composition as the bulk film 245, the adhesion does not violate lattice match.

Although an example is provided in which a gap is filled, the technique described above may also be used to fill a trench, and is particularly advantageous for a high aspect ratio trench.

The above described method for filling a trench or gap is especially advantageous, where the trench or gap has a critical dimension of about 180 angstroms or less prior to the liner applying step. This may include, for example, technologies with line critical dimensions of 90 nanometers, or where the trench or gap has a critical dimension prior to the liner applying step of about an order of magnitude of an atomic group used to form the liner.

The gap filling methods described above can avoid the void formation problem that was encountered when bulk fill techniques such as HDP-CVD and SA-CVD were used. ALD provides essentially perfect conformity to the surface on which the monolayers are deposited.

ALD systems typically have at least two gas delivery systems (for the at least two precursors) with valves having high actuation speed to closely control the introduction of each precursor. The gases are introduced into a heated deposition chamber. Vacuum pumping controls the system pressure and gas flow, and purges the chamber after each cycle. The tool will apply HDP as a basic configuration and design, and the pumping efficiency should be improved and the pump made more powerful to meet ALD's faster pump output requirement and the lower processing pressure.

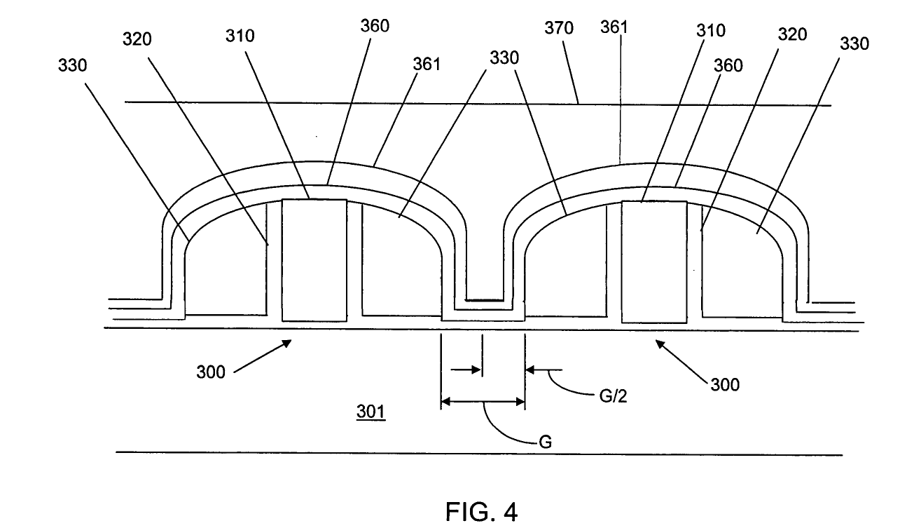

FIG. 4 shows a second exemplary embodiment, in which ALD is used for applying an etch stop layer.

A method for applying an etch stop layer 360 over a pair of semiconductor devices 300 formed above a substrate 301 includes applying a first etch stop layer 360 by atomic layer deposition. The first etch stop layer 360 comprises a first portion that is above each of the pair of devices 300 and a second portion that is a liner in a trench or gap between the pair of devices. As in the embodiment of FIG. 3, one or more ALD cycles is performed to deposit an etch stop layer 360 of a desired thickness. Any desired number of ALD cycles may be used, the number of cycles determined by the desired thickness and the known constant thickness of a monolayer of each precursor.

The composition of the etch stop material 360 depends on the etchant employed to etch the material deposited on the etch stop layer, and may be, for example, silicon nitride. Alternative etch stop layers may include SiON and composite film of both films.

In addition to the one or more layers 360 deposited by ALD, a second etch stop layer 361 may be applied for a wider process window on contact etching. Even where a bulk fill CVD process is used to form the second etch stop layer 361, the presence of the first etch stop layer 360 ensures complete coverage over the wafer (or chip) with at least a minimum thickness throughout. The bulk fill process may be used to form the second etch stop layer 361 to reduce the total for depositing a combined etch stop layer 360, 361 having a desired total thickness.

When the material applied by ALD is used as an etch stop layer 360, it is not necessary to completely fill the gap with the material used for the etch stop layer. As shown in FIG. 4, layer 360 provides a thin and uniform etch stop layer by ALD. Optionally, the etch stop layer may be thick enough to completely fill the gap (not shown in FIG. 4), except for an approximately V shaped space similar to that shown in FIG. 3.

For the etch stop layer application, the etch stop layer 360, 361 has different properties from the Oxide (bulk material) 370 formed over the etch stop layer. One can use a different gas ratio to obtain a different stop layer (also possess a good gap-fill ability).

FIG. 4 shows a structure according to one embodiment. The structure comprises: a pair of semiconductor devices 300 formed above a substrate 301, with a trench or gap therebetween, a liner 360 formed in the trench or gap by atomic layer deposition to partially fill the trench or gap, and a layer of material 370 filling the gap. The liner 360 may be made of phospho silicate glass formed from precursors from the group consisting of TEOS, SiH₄, PH₃ and B₂H₆. The liner 360 may be applied by: (a) depositing a monolayer of SiH₄, (b) depositing a monolayer of either PH₃ or B₂H₆; and (c) applying a low powered O₂/Ar plasma. In this example, the trench or gap has a dimension of about 180 angstroms or less prior to applying the liner, which is of about an order of magnitude of an atomic group used to form the liner.

ALD is advantageous for forming an etch stop layer when a gap has a critical dimension of about 180 angstroms or less prior to the etch stop layer applying step, or when the gap has a critical dimension prior to the etch stop layer applying step of about an order of magnitude of an atomic group used to form the etch stop layer.

Good uniformity of layer thickness is provided for thin films with less than 20 angstrom thickness per cycle. ALD can be performed with a low thermal budget. The above-described procedure is especially advantageous for advanced technologies with dimensions less than 90 nanometers.

Although an example is provided in which PSG is deposited for gap filling by ALD, a variety of other materials may be deposited for gap filling using the ALD method. For example, Silane-based BPSG may be used.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. A method for filling a trench or gap between a pair of semiconductor devices formed above a substrate, comprising the steps of:
applying a liner in a trench or gap between a pair of devices by atomic layer deposition to partially fill the trench or gap, wherein the liner is formed of phospho silicate glass; and
filling the trench or gap by a bulk fill process.

2. (canceled)

3. The method of claim 1, wherein the liner is formed from precursors from the group consisting of TEOS, SiH₄, PH₃ and B₂H₆.

4. A method for filling a trench or gap between a pair of semiconductor devices formed above a substrate, comprising the steps of:
applying a liner in a trench or gap between a pair of devices by atomic layer deposition to partially fill the trench or gap, wherein the liner applying step includes:
(a) depositing a monolayer of SiH₄, and
(b) depositing a monolayer of either PH₃ or B₂H₆; and filling the trench or gap by a bulk fill process.

5. The method of claim 4, wherein the liner applying step further comprises (c) applying a low powered O2/Ar plasma after the monolayer of either PH₃ or B₂H₆.

6. The method of claim 5, wherein steps (a), (b) and (c) are repeated a sufficient number of times to fill a dimension of the trench or gap.

7. The method of claim 4, wherein the liner applying step includes controlling the material components of the liner by controlling a gas ratio of PH₃ and SiH₄.

8. The method of claim 1, wherein the bulk fill process is one of the group consisting of plasma enhanced chemical vapor deposition (CVD) or high density plasma CVD.

9. The method of claim 1, wherein the trench or gap has a dimension of about 180 angstroms or less prior to the liner applying step.

10. A method for filling a trench or gap between a pair of semiconductor devices formed above a substrate, comprising the steps of:
applying a liner in a trench or gap between a pair of devices by atomic layer deposition to partially fill the trench or gap, wherein the trench or gap has a dimension prior to the liner applying step of about an order of magnitude of an atomic group used to form the liner; and
filling the trench or gap by a bulk fill process.

11. A method for applying an etch stop layer over a pair of semiconductor devices formed above a substrate, the method comprising:
applying a first etch stop layer by atomic layer deposition, the first etch stop layer comprising a first portion that is above each of the pair of devices and a second portion that is a liner in a gap between the pair of devices,
wherein the gap has a dimension prior to the etch stop layer applying step of about an order of magnitude of an atomic group used to form the liner.

12. The method of claim 11, wherein the gap has a dimension of about 180 angstroms or less prior to the etch stop layer applying step.

13. The method of claim 11, further comprising applying a second etch stop layer above the first etch stop layer by chemical vapor deposition.

14-19. (canceled)

20. The method of claim 1, wherein the trench or gap has a dimension prior to the liner applying step of about an order of magnitude of an atomic group used to form the liner.

21. The method of claim 4, wherein the trench or gap has a dimension prior to the liner applying step of about an order of magnitude of an atomic group used to form the liner.

22. The method of claim 10, wherein the liner is formed from precursors from the group consisting of TEOS, SiH₄, PH₃ and B₂H₆.

23. The method of claim 10, wherein the liner is formed of phospho silicate glass.

24. The method of claim 10, wherein the liner applying step reduces the trench or gap to a relatively shallow approximately V-shaped space.
